(19) United States
(12) Patent Application Publication
(10) Pub. No.: US 2020/0199774 A1
(43) Pub. Date: Jun. 25, 2020

(54) Sample Rod Center Slab Resistivity Measurement With Four-Point Probe During Single Crystal Silicon Ingot Production

(71) Applicant: GLOBALWAFERS CO., LTD., Hsinchu (TW)

(72) Inventors: HyungMin Lee, Chungcheongnam-do (KR); JaeWoo Ryu, Chesterfield, MO (US); Richard Phillips, St. Peters, MO (US); YoungJung Lee, Chungcheongnam-do (KR); Carissima Marie Hudson, Saint Charles, MO (US)

(21) Appl. No.: 16/230,517

(22) Filed: Dec. 21, 2018

(51) Int. Cl. C30B 15/10; C30B 15/00; C30B 15/04; C30B 15/14; C30B 15/20; C30B 29/06

(52) U.S. Cl. CPC C30B 15/10; C30B 15/002; C30B 15/04; C30B 29/06; C30B 15/20; C30B 15/007; C30B 15/14

(57) ABSTRACT

Methods for forming single crystal silicon ingots with improved resistivity control are disclosed. The methods involve growth of a sample rod. The sample rod may have a diameter less than the diameter of the product ingot. The sample rod is cropped to form a center slab. The resistivity of the center slab may be measured directly such as by a four-point probe. The sample rod may be annealed in a thermal donor kill cycle prior to measuring the resistivity.

### FIELD OF THE DISCLOSURE

The field of the disclosure relates to methods for forming single crystal silicon ingots with improved resistivity control and, in particular, methods that involve growth and resistivity measurement of a center slab cropped from a sample rod having a diameter less than a product ingot.

### BACKGROUND

Single crystal silicon, which is the starting material for most processes for the fabrication of semiconductor electronic components, is commonly prepared by the so-called Czochralski (CZ) process wherein a single seed crystal is immersed into molten silicon and then grown by slow extraction. Molten silicon is contaminated with various impurities, among which is mainly oxygen, during the time it is contained in a quartz crucible. Some applications, such as advanced wireless communication applications, insulated gate bipolar transistors (IGBT) and low power, low leakage devices, require wafers with a relatively high resistivity such as 1500 ohm-cm (Ω-cm) or more.

Highly pure polysilicon is used for high resistivity ingot production. Highly pure polysilicon is characterized by a spread in the impurity profile which causes a wide spread in the intrinsic resistivity range of the un-doped material and its type. Targeting of the seed-end resistivity in such high or ultra-high resistivity materials is difficult due to the variability of boron and phosphorous in the starting material (including surface boron and phosphorous in the polysilicon material) and due to impurities in the crucible, and/or oxygen levels which alter the resistivity after a thermal donor kill cycle. Further, such high resistivity applications may be susceptible to increased error in resistivity measurement.

A need exists for methods for preparing high resistivity silicon ingots that allow the impurity concentration and/or resistivity of the polysilicon starting material to be sampled relatively quickly and reliably with a relatively small amount of silicon being consumed for resistivity measurement.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for producing a single crystal silicon ingot from a silicon melt held within a crucible. Polycrystalline silicon is added to the crucible. The polycrystalline silicon is heated to cause a silicon melt to form in the crucible. A sample rod is pulled from the melt. A slab is formed from the sample rod. A resistivity of the slab is measured by contacting the slab with a four-point probe. A product ingot is pulled from the melt.

Another aspect of the present disclosure is directed to a method for producing a single crystal silicon ingot from a silicon melt held within a crucible. Polycrystalline silicon is added to the crucible. The polycrystalline silicon is heated to cause a silicon melt to form in the crucible. A sample rod is pulled from the melt. A slab is cropped from the sample rod. The slab is annealed to annihilate thermal donors. The annealed slab is lapped to form a lapped surface. A resistivity of the slab is measured by contacting the lapped surface with a four-point probe. An amount of dopant added to the melt is adjusted based at least in part on the measured resistivity of the slab to achieve a target resistivity in a product ingot. The product ingot is pulled from the melt.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic side view of a pulling apparatus for forming a single crystal silicon ingot;

FIG. 2 is a sample rod grown from a silicon melt;

FIG. 3 is a schematic perspective view of a sample rod showing two crop planes along which the rod is cropped to form a center slab;

FIG. 4 is a schematic perspective view of a cropped sample rod that includes a center slab;

FIG. 5 is an I-V curve used to measure resistivity;

FIG. 6 is a scatter plot of the resistivity of a sample rod at various positions from the seed end;

FIG. 7 is a scatter plot of the resistivities of a sample rod ground flat and of a short ingot and product ingot;

FIG. 8A is a schematic top view of three sample rods that were successively ground to form planar segments (flats);

FIG. 8B is a scatter plot of the resistivities of the successively ground sample rods of FIG. 8A and of a short ingot and product ingot;

FIG. 9 is a scatter plot of the resistivities of half cut sample rods and center slabs cropped from a sample rod and of a short ingot and a product ingot;

FIG. 10 is a scatter plot of the resistivities of a successively ground sample rod and a center slab cropped from a sample rod and of a short ingot and a product ingot; and

FIG. 11 is a scatter plot of the resistivities of a center slab cropped from a product ingot as measured by a two-point probe and as measured by a four-point probe and of a short ingot and product ingot.

Corresponding reference characters indicate corresponding parts throughout the drawings.

### DETAILED DESCRIPTION

Provisions of the present disclosure are directed to methods for producing a single crystal silicon ingot by the Czochralski method in which a sample rod is grown to determine the resistivity of the melt. The sample rod has a diameter less than the product ingot. The sample rod is slabbed and the resistivity of the slab is measured such as by a four-point probe.

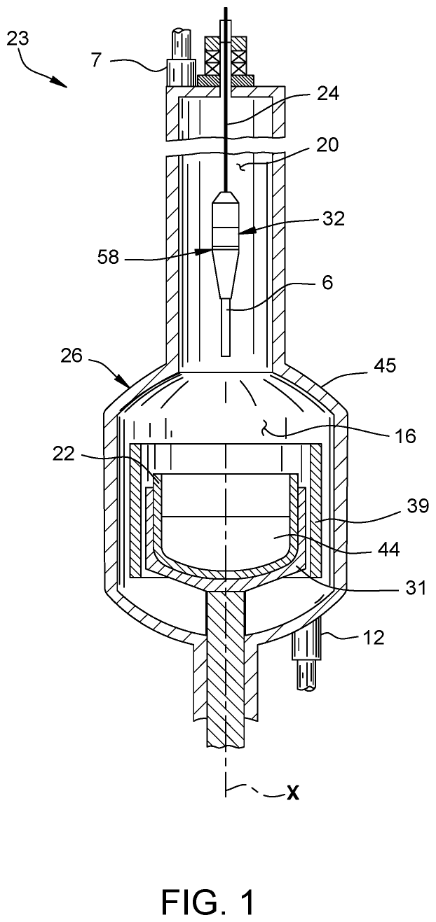

In accordance with embodiments of the present disclosure and with reference to FIG. 1, the product ingot is grown by the so-called Czochralski process in which the ingot is withdrawn from a silicon melt 44 held within a crucible 22 of an ingot puller 23. The ingot puller 23 includes a housing 26 that defines a crystal growth chamber 16 and a pull chamber 20 having a smaller transverse dimension than the growth chamber. The growth chamber 16 has a generally dome shaped upper wall 45 transitioning from the growth chamber 16 to the narrowed pull chamber 20. The ingot puller 23 includes an inlet port 7 and an outlet port 12 which may be used to introduce and remove a process gas to and from the housing 26 during crystal growth.

The crucible 22 within the ingot puller 23 contains the silicon melt 44 from which a silicon ingot is drawn. The silicon melt 44 is obtained by heating the polycrystalline silicon charged to the crucible 22 to cause it to melt. The crucible 22 is mounted on a turntable 31 for rotation of the crucible 22 about a central longitudinal axis X of the ingot puller 23.

A heating system 39 (e.g., an electrical resistance heater) surrounds the crucible 22 for melting the silicon charge to produce the melt 44. The heating system 39 may also extend below the crucible as shown in U.S. Pat. No. 8,317,919. The heating system 39 is controlled by a control system (not shown) so that the temperature of the melt 44 is precisely controlled throughout the pulling process. Insulation (not shown) surrounding the heating system 39 may reduce the amount of heat lost through the housing 26. The ingot puller 23 may also include a heat shield assembly (not shown) above the melt surface for shielding the ingot from the heat of the crucible 22 to increase the axial temperature gradient at the solid-melt interface.

A pulling mechanism (not shown) is attached to a pull wire 24 that extends down from the mechanism. The mechanism is capable of raising and lowering the pull wire 24. The ingot puller 23 may have a pull shaft rather than a wire, depending upon the type of puller. The pull wire 24 terminates in a pulling assembly 58 that includes a seed crystal chuck 32 which holds a seed crystal 6 used to grow the silicon ingot. In growing the ingot, the pulling mechanism lowers the seed crystal 6 until it contacts the surface of the silicon melt 44. Once the seed crystal 6 begins to melt, the pulling mechanism slowly raises the seed crystal up through the growth chamber 16 and pull chamber 20 to grow the monocrystalline ingot. The speed at which the pulling mechanism rotates the seed crystal 6 and the speed at which the pulling mechanism raises the seed crystal (i.e., the pull rate v) are controlled by the control system.

A process gas is introduced through the inlet port 7 into the housing 26 and is withdrawn from the outlet port 12. The process gas creates an atmosphere within the housing 26 and the melt and atmosphere form a melt-gas interface. The outlet port 12 is in fluid communication with an exhaust system (not shown) of the ingot puller.

In this regard, the ingot puller 23 shown in FIG. 1 and described herein is exemplary and other crystal puller configurations and arrangements may be used to pull a single crystal silicon ingot from a melt unless stated otherwise.

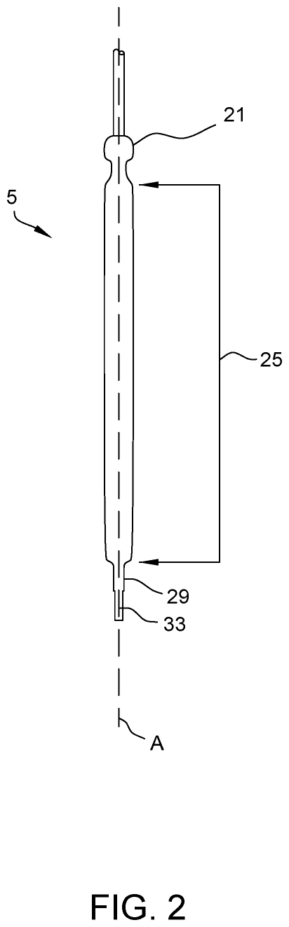

In accordance with embodiments of the present disclosure, after polycrystalline silicon is added to the crucible 22 and the heating system 39 is operated to melt-down the polycrystalline silicon, a sample ingot or rod is pulled from the melt. An example sample rod 5 is shown in FIG. 2. The rod 5 includes a crown portion 21 in which the rod transitions and tapers outward from the seed to reach a target diameter. The rod 5 includes a constant diameter portion 25 or cylindrical main body or simply “body”, of the crystal which is grown by increasing the pull rate. The main body 25 of the sample rod 5 has a relatively constant diameter. The rod 5 includes a tail or end-cone 29 in which the rod tapers in diameter after the main body 25. When the diameter becomes small enough, the rod 5 is then separated from the melt. The rod 5 has a central longitudinal axis A that extends through the crown 21 and a terminal end 33 of the ingot.

The growth conditions of the sample rod 5 may be selected from generally any of the suitable growth conditions available to those of skill in the art. The sample rod 5 may be a single crystal with a body of the sample rod having zero dislocations. The sample rod 5 may be grown with a locked seed lift (i.e., fixed pull speed with varying diameter such as +/−about 5 mm) or active seed lift (pull speed varied to maintain target diameter).

The sample rod 5 has a diameter less than the product ingot that is grown after the sample rod. For example, the diameter of the sample rod may be less than 0.75 times the diameter of the product ingot, less than 0.50 times, less than about 0.25 times or less than 0.1 times the diameter of the product ingot. In some embodiments, the diameter of the sample rod is less than about 150 mm or less than about 100 mm, less than about 50 mm, less than about 25 mm, or less than about 20 mm (e.g., from about 5 mm to about 150 mm, from about 5 mm to about 100 mm, from about 5 mm to about 50 mm, from about 5 mm to about 25 mm or from about 10 mm to about 25 mm). Generally, the diameter of the rod 5 is measured by measuring the rod along several axial locations (e.g., within a constant diameter portion of the rod if the rod has a crown and/or tapered end) and averaging the measured diameters (e.g., measuring 2, 4, 6, 10 or more diameters along the length and averaging). In some embodiments, the largest diameter of the sample rod is less than about 150 mm or less than about 100 mm, less than about 50 mm, less than about 25 mm, or less than about 20 mm (e.g., from about 5 mm to about 150 mm, from about 5 mm to about 100 mm, from about 5 mm to about 50 mm, from about 5 mm to about 25 mm or from about 10 mm to about 25 mm).

In some embodiments, the rod 5 has a diameter that generally corresponds to the diameter of the neck portion of a product ingot grown in the crystal puller. For example, the rod may have a diameter of less than 50 mm, less than 25 mm, or less than 20 mm.

The sample rod 5 may have any suitable length. In some embodiments, the rod (e.g., after cropping) has a length of less than about 300 mm, less than about 200 mm or less than about 100 mm (e.g., from about 25 mm to about 300 mm).

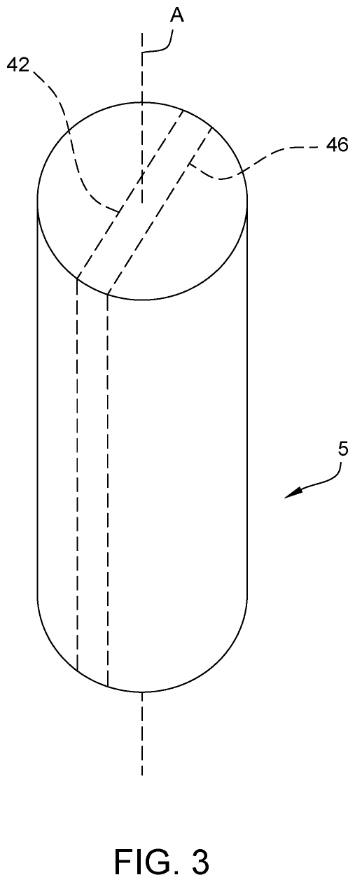

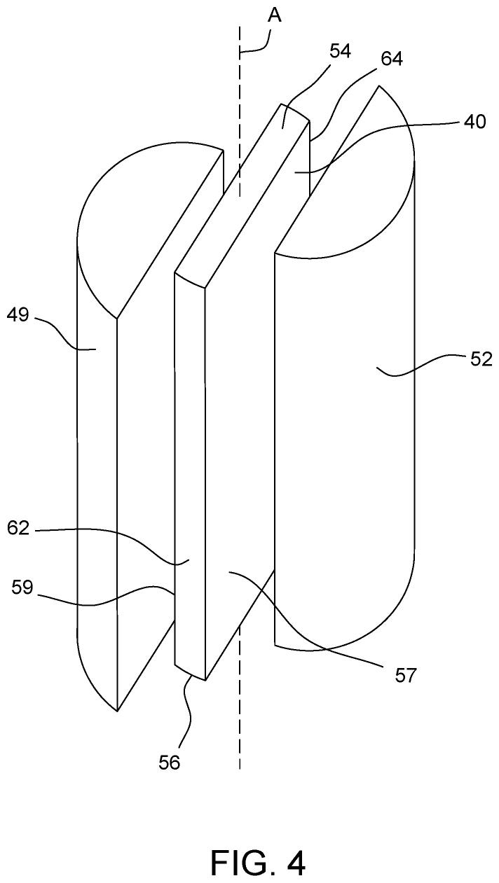

After the sample rod 5 is grown, the sample rod is processed to form a center slab 40 (FIG. 4). The crown and tail of the sample rod 5 may be removed, such as by use of a wire saw. As shown in FIG. 4, the sample rod 5 is then cropped to form the slab 40. The sample rod 5 may be cropped by a tabletop cutting machine (e.g., Minitom, available from Streuers (Westlake, Ohio)) or by use of a diamond wire saw (e.g., DTW wire saw). The sample rod 5 is cropped along a first crop plane 42 (FIG. 3) and is cropped along a second crop plane 46 to form first and second crop portions 49, 52 (FIG. 4) and the slab 40. The first crop plane 42 and the second crop plane 46 are parallel to each other and are parallel to the central longitudinal axis A of the sample rod 5. The slab 40 may have any suitable thickness for resistivity measurement such as, for example, between about 5 mm and about 0.1 mm, between about 3 mm and about 0.5 mm, between about 3 mm to about 1 mm, between 2 mm and 1 mm or a thickness of about 1.1 mm. The slab 40 may be generally square or rectangular in cross-section. The first and second sides 62, 64 of the slab 40 may be slightly rounded due to the contour of the sample rod 5 or the slab 40 may be further cropped to form planar sides 62, 64.

Generally, the center slab 40 includes at least portion of the central axis A of the uncropped sample rod 5. In some embodiments, the cropping method may be variable to account for axial non-uniformity in the sample rod diameter to allow the center slab 40 to capture as much of the axisymmetric center line of the rod 5 as possible. For example, the slab 40 may include at least about 10% of the central axis A of the sample rod 5 (i.e., the sample rod just prior to cropping to form the center slab), or at least about 25%, at least about 50%, at least about 75%, or at least about 90% of the central axis A of the sample rod 5. In some embodiments, after cropping, the central axis A of the cropped sample rod 5 extends through the entire length of the slab 40 (e.g., from first end 54 to second end 56 of the slab 40).

In some embodiments, the center slab 40 is subjected to a rapid thermal anneal before measuring the resistivity. The rapid thermal anneal may act as a thermal donor kill cycle (i.e., annihilation of thermal donors) by dissociating interstitial oxygen clusters. In some embodiments, the anneal is performed at a temperature of about 500° C. or more, about 650° C. or more or about 800° C. or more (e.g., 500° C. to about 1000° C., from about 500° C. to about 900° C. or from about 650° C. to about 1100° C.) for at least about 5 seconds, at least about 30 seconds or at least about 1 minute or more (e.g., from about 5 seconds to 15 minutes, from about 5 seconds to about 5 minutes or from about 5 seconds to about 3 minutes). The center slab 40 may be etched (e.g., mixed acid etched) for oxygen measurement prior to the rapid thermal anneal. In some embodiments, rather than annealing the cent slab 40, the sample rod 5 is subject to the thermal donor kill anneal before cropping the rod 5 to form the center slab 40.

The first and second cropped, planar surfaces 57, 59 of the slab 40 may be ground to flatten the surfaces. In some embodiments, the slab 40 is lapped before resistivity measurement to form a lapped surface with reduced surface morphology (e.g., before or after the thermal donor kill cycle). For example, the slab 40 may be contacted with an alumina slurry or silicon carbide slurry. In some embodiments, the average particle size of the particles of the slurry is less than about 10 μm. The lapping time may be at least about 5 minutes or at least about 10 minutes with a pressure of at least about 5 kgf or at least about 10 kgf.

The resistivity of the melt from which the product ingot is grown may be determined by measuring the resistivity of the slab 40. In some embodiments of the present disclosure, current is driven through the slab 40 and a resistivity probe is contacted at one or more locations along the length of slab 40. Current may be applied to the rod 5 through one of the ends 54, 56.

In some embodiments, the resistivity of the slab 40 is measured by a four-point resistivity probe (e.g., an in-line four-point probe) in which all four probe tips contact the slab 40. The slab 40 may be mounted in a jig during resistivity measurement. In accordance with some embodiments, a current (e.g., direct current) is passed through the slab 40 between the outer probe pins and the resulting potential difference is measured between the inner probe pins. The resistivity is calculated from the measured current and potential values based on the factors appropriate from the slab geometry. In this regard, the resistivity may be measured in accordance with SEMI MF84-0307 entitled “Test Method for Measuring Resistivity of Silicon Wafers with an In-line Four-Point Probe” and/or SEMI MF43-0705 entitled “Test Methods for Resistivity of Semiconductor Materials”, which are incorporated herein by reference for all relevant and consistent purposes. The voltage may be measured at various points along the length of the slab 40. The measured voltages and the sample length and average thickness may be used to calculate the resistivity such as by determining the slope of a current-voltage curve (e.g., Example 1 below).

In some embodiments, the sample rod 5 and slab 40 have a relatively low oxygen content such as an oxygen content of less than about 5.5 ppma. In other embodiments, the oxygen content of the sample rod 5 and slab 40 is less than 5.2 ppma, less than 5.0 ppma, less than 3.5 ppma, less than about 3 ppma or even less than about 2.5 ppma. In some embodiments, the sample rod 5 and slab 40 produced from the sample rod 5 is free of dislocations.

The measured resistivity of the slab 40 provides information related to the resistivity of the polycrystalline silicon melt in the crucible (i.e., the starting dopant impurity concentration (i.e., net donor-acceptor concentration)). The measured resistivity of the slab 40 may be used to adjust the manufacturing conditions for the subsequently grown ingot. For example, an amount of dopant may be added to the polycrystalline silicon melt with the amount of dopant being adjusted based at least in part on the measured resistivity (e.g., by use of a model that predicts product ingot resistivity). Suitable dopants include p-type dopants such as boron, aluminum, gallium and indium and n-type dopants such as phosphorous, arsenic and antimony.

In some embodiments, an amount of dopant is added to the melt before growing the sample rod and measuring the resistivity of the rod and an amount of dopant (e.g., the same dopant or a different dopant) is added after the sample rod is grown. In other embodiments, all dopants (if any) are added after the sample rod is grown and the resistivity is measured (e.g., boron or phosphorous).

The polysilicon to which the dopant is added and from which a sample ingot and product ingot is pulled may be semiconductor grade polysilicon. When semiconductor grade polysilicon is used, in some embodiments the polysilicon has a resistivity greater than 4,000 Ω-cm and contains no more than 0.02 ppba boron or phosphorous.

After the sample rod is pulled and, optionally, dopant is added to the melt, a product ingot is withdrawn from the melt. The product ingot has a diameter greater than the diameter of the sample rod (i.e., the diameter of the constant diameter portion of the sample rod is less than the diameter of the constant diameter portion of the ingot). The product ingot may have a diameter of about 150 mm or, as in other embodiments, about 200 mm, about 300 mm or more (e.g., 450 mm or more).

In some embodiments, polycrystalline silicon is not added during the growth of the ingot (e.g., as in a batch process). In other embodiments, polycrystalline silicon is added to the melt as the product ingot is grown (e.g., as in a continuous Czochralski method).

The amount of dopant added to the melt (with or without addition of a first dopant before the sample rod is grown) may be controlled to achieve a target resistivity in at least a portion of the main body of the ingot (e.g., a prime portion of the ingot). In some embodiments, the target resistivity is a minimum resistivity. In some embodiments, the entire length of the ingot (e.g., length of the body of the ingot) has the target resistivity (e.g., minimum resistivity). In some embodiments, the target resistivity of at least a portion of the product ingot is a minimum resistivity of at least about 1,500 Ω-cm or, as in other embodiments, at least about 2,000 Ω-cm, at least about 4,000 Ω-cm, at least about 6,000 Ω-cm, at least about 8,000 Ω-cm, at least about 10,000 Ω-cm or from about 1,500 Ω-cm to about 50,000 ohm-cm or from about 8,000 Ω-cm to about 50,000 Ω-cm. Alternatively or in addition, the sample rod (and the resulting center slab) may have a resistivity of at least about 1,500 Ω-cm, or at least about 2,000 Ω-cm, at least about 4,000 Ω-cm, at least about 6,000 Ω-cm, at least about 8,000 Ω-cm, at least about 10,000 Ω-cm, from about 1,500 Ω-cm to about 50,000 ohm-cm or from about 8,000 Ω-cm to about 50,000 Ω-cm.

Compared to conventional methods for producing a single crystal silicon ingot, the methods of the present disclosure have several advantages. Relatively high purity polysilicon that is used to produce relatively high resistivity single crystal silicon has a wide spread in boron and phosphorous impurity amounts which causes a wide spread in the intrinsic resistivity. By growing a sample rod with relatively small diameter (e.g., less than the product ingot such as less than 100 mm, less than 50 mm, less than 25 mm or even less than 10 mm compared to sample ingots that have a size substantially the same of the product ingot such as at least 200 mm) and forming a slab from the sample rod, the resistivity of the melt can be sampled relatively quickly and reliably.

The measured resistivity may be used for more precise addition of dopant to achieve better targeting of high resistivity or ultra-high resistivity products (e.g., at least about 3000 ohm-cm, 5000 ohm-cm or at least 7000 ohm-cm or more) and, in particular, for better seed-end resistivity targeting. The relatively small diameter sample rod consumes relatively little amount of the melt (e.g., less than 1 kg, less than 0.5 kg or about 0.25 kg or less compared to a full diameter short ingot which may consume 15 kg, 20 kg or 50 kg or more of the melt) and reduces impurity build-up attributed to the sampling process. The sample rod may be grown relatively quickly (e.g., about 12, 10 or even 5 hours or less compared to a full size short ingot which may involve 20 hours, 30 hours, 40 hours, or 50 hours of growth time). The slab cropped from the sample rod may have a relatively low oxygen content (e.g., such as less than about 5 ppma or less than 4 ppma) which may improve the accuracy of the resistivity measurement (e.g., the accuracy after a thermal donor kill cycle).

Variability in the measurement of resistivity from the sample rod may be caused by (1) diameter correction for resistivity as measured by a two-point probe, contact noise due to preparation of a planar segment on the sample rod, and/or (3) large surface morphology variation. By forming a slab from the sample rod, the resistivity may be measured relatively near the axisymmetric center of the sample rod. This improves the accuracy of the resistivity measurement as radial variation in resistivity is reduced or eliminated. In embodiments in which the slab is lapped to reduce morphology caused by grinding and to improve thickness uniformity, the resistivity measurement may be more accurate. In embodiments in which a four-point probe is used to measure resistivity, the resistivity measurement may be further improved.

Reduced sample rod growth time and reduced resistivity measurement times reduce the processing time at which the resistivity measurement is provided (e.g., 20, 30 or 40 hours in reduction of process time) which reduces impurity buildup caused by crucible dissolution. Reducing impurities also improves resistivity predictability for future runs. Reduction in the hot hour time for each batch (i.e., between product ingots) allows for the crucible to recharged in additional cycles without an increase in loss of zero dislocation.

### EXAMPLES

The processes of the present disclosure are further illustrated by the following Examples. These Examples should not be viewed in a limiting sense.

### Example 1: Determination of Resistivity from I-V Curve

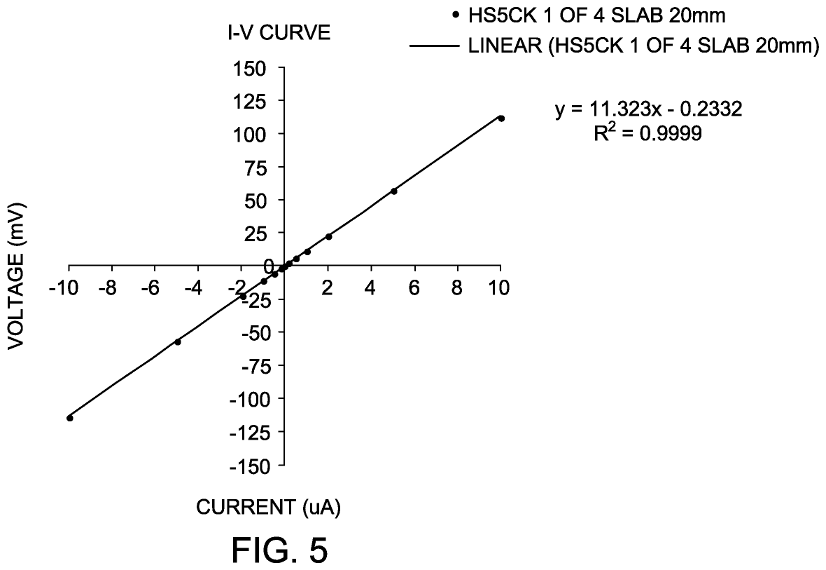

Voltage of a sample rod was measured axially with the applied current and measured voltage being recorded. FIG. 5 shows the I-V curve that was generated. Using the geometry of the sample and the slope of the I-V curve, the resistivity was determined to be 6139 ohm-cm for the sample. Resistivity may be similarly determined for a center slab cropped from the sample rod.

### Example 2: Comparison of Short Ingot vs Sample Rod

A single crystal short sample ingot (“Short Ingot”) having a diameter of about the size of the product ingot (e.g., about 200 mm in a 200 mm pulling apparatus) was grown in a pulling apparatus similar to FIG. 1. The crystal was cropped and subjected to a mixed acid etch (MAE). The crystal slug was rapid thermal annealed at 800° C. for 3 minutes and lapped. The slug was contacted with a four-point probe to measure the resistivity with the resistivity being averaged over three measurements.

A sample rod (“Sample Rod”) was grown in locked seed lift mode in the same pulling apparatus after the short ingot was grown. The diameter of the rod varied across its length and was within a range of 17-23 mm with an average of 20 mm. The sample rod was cropped and ground to form a flat segment that extended from one end to the other end of the rod. The rod was rapid thermal annealed at 720° C. for 2 minutes. The resistivity of the ingot was measured with a two-point probe. The differences between the growth conditions are shown in Table 1 below:

TABLE 3
Growth Conditions for Sample Ingot 200 mm in Diameter
and a Sample Rod ~17-23 mm in Diameter

| | Short Ingot | Sample Rod |
|---|---|---|
| Diameter (mm) | 207 | ~17-23 |
| Weight (kg) | 31 | 0.11 |
| Length (mm) | 250 | 200 |
| Process Time (hr) | 25 | 5 |
| Resistivity Sample | 26 | 6 |
| Preparation Time (hr) | | |
| Total time (hr) | 51 | 11 |

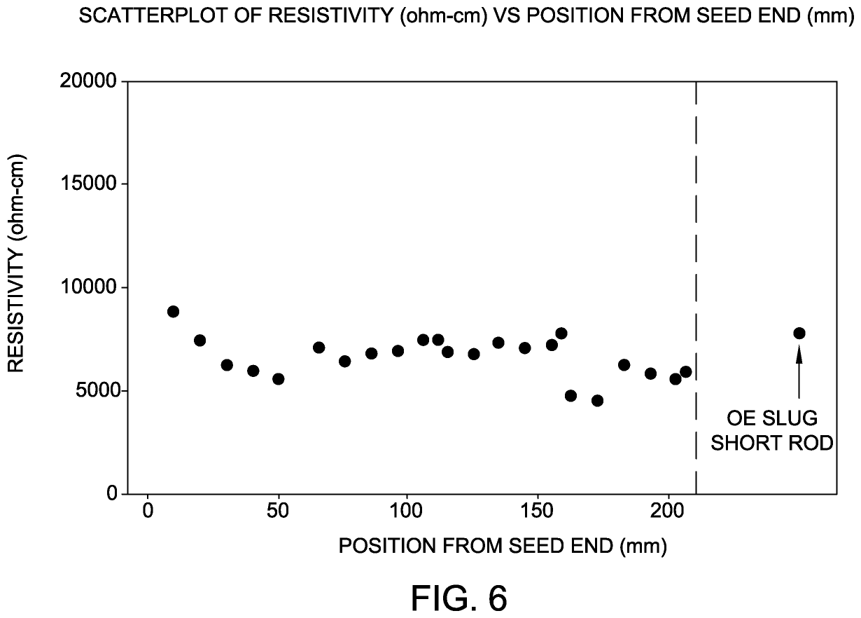

The measured resistivities along the length of the sample rod and the resistivity of a slug from the sample ingot are shown in FIG. 6.

The sample preparation time for the short ingot was 26 hours and involved cropping, mixed-acid etch, rapid thermal anneal, slab cutting, grinding (e.g., with a diamond grinder), lapping and resistivity measurement. The sample preparation time for the sample rod was 6 hours and involved cropping, mixed-acid etch, rapid thermal anneal, flat grinding (with a diamond pad), lapping and resistivity measurement. The sample rod process time was 20% of the short ingot process time (5 hours vs 25 hours) and the total time of the sample rod was 22% of the total time of the short ingot total time (11 hours vs 51 hours). In some embodiments, sample rod process time and total time ranges from about 15% to about 25% of the short ingot process time and total time.

### Example 3: Comparison of Sample Rod Resistivity, Short Ingot Resistivity and Product Ingot Seed-End Resistivity

A single crystal short sample ingot (“Short Ingot”) and two sample rods (“Sample Rod”) were grown under the conditions of Example 2. One sample rod was grown before the short ingot was grown and one sample rod was grown after the short ingot was grown. A product ingot was also grown with a target seed-end resistivity of about 8,000 ohm-cm (p-type). Because the short ingot had a resistivity of about 5,000 ohm-cm, an amount of phosphorous dopant was added to target a resistivity of at least 7,500 ohm-cm in the product ingot.

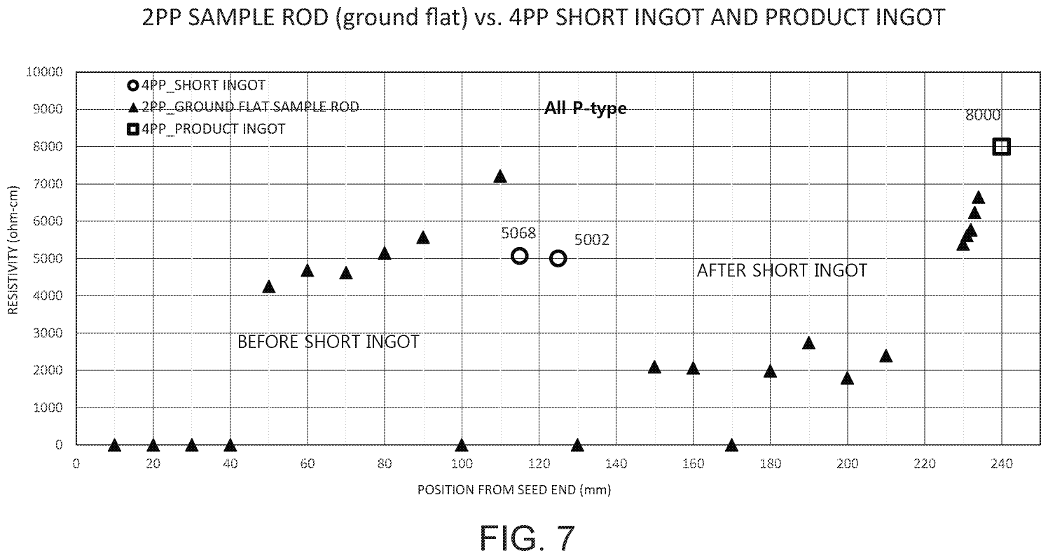

The resistivity of the sample rod was measured by a two-point probe and the resistivities of the slugs of the short ingot were measured by a four-point probe with the results being shown in FIG. 7. The resistivity of the product ingot near the seed-end is also shown in FIG. 7. Variation in the two-point measurement of the sample rod may be observed from FIG. 7. The variation in the resistivity measurement in the sample rod grown before the short ingot would cause over doping (e.g., if an average had been used). Similar variation (not shown) was observed when the sample rod was cut in half (center cut).

### Example 4: Variability in Resistivity Measurement Verse Proximity to Axisymmetric Center of Sample Rod

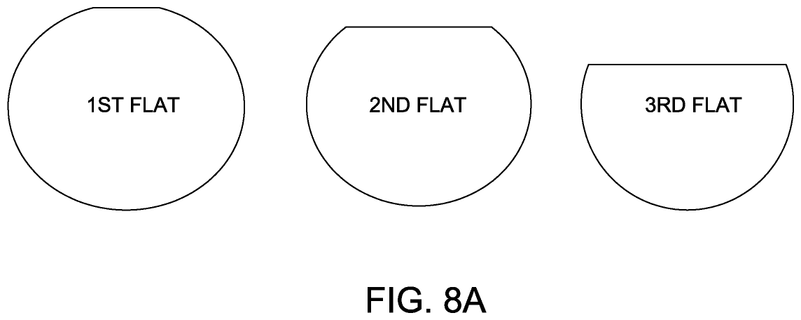

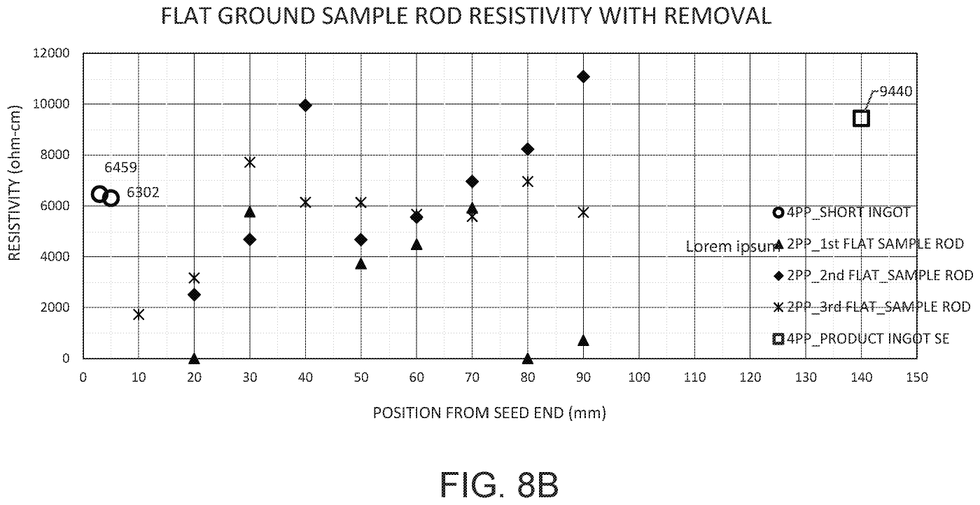

A single crystal short sample ingot (“Short Ingot”) and a sample rod (“Sample Rod”) were grown under the conditions of Example 2. A product ingot was also grown with a target seed-end resistivity of about 7,500 ohm-cm (p-type). The sample rod was ground three times to form planar segments on the sample rod that were progressively closer to the central axis of the sample rod (FIG. 8A). The resistivity along the rod was measured by a two-point probe after each planar segment was formed with the resistivities of each flat being shown in FIG. 8B. The short ingot resistivity that was used to determine the dopant amount for the product ingot and the product rod resistivity are also shown in FIG. 8B.

As shown in FIG. 8B, the axial measurements for each flat become flatter and less axially variable with each removal. For each flat, the initial seed resistivity of the sample rod is well below the mid to late body average of the rod. Each flat average would have been below the short ingot average which would cause additional phosphorus dopant to be used which would drive the product ingot away from the 7,500 ohm-cm target.

### Example 5: Comparison of Resistivity Measurements of Center Cut Sample Rod Verse Center Slab

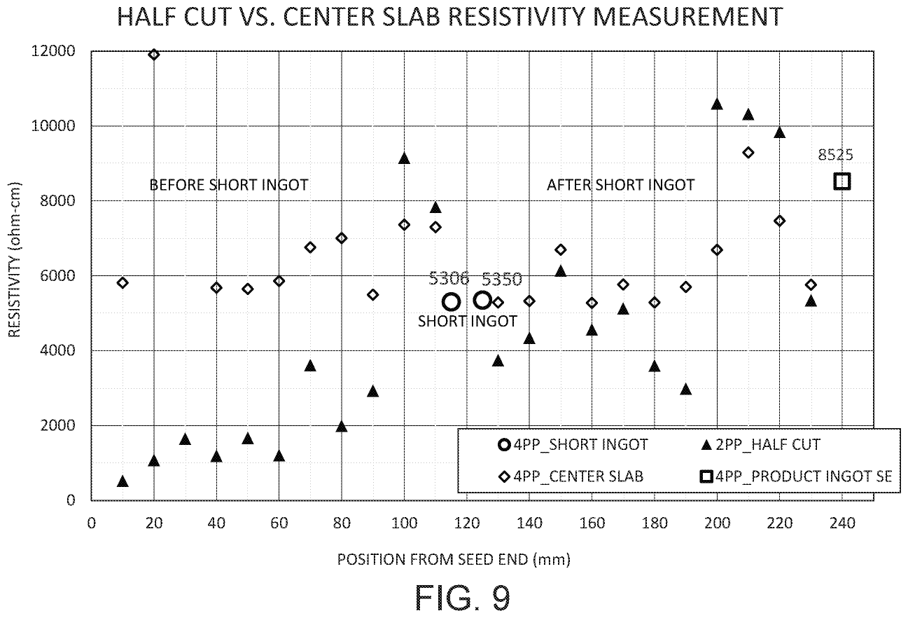

Sample rods were grown under the conditions of Example 2 just prior to growth of a short ingot. One sample rod was center cut and one sample rod was processed to form a center slab about 1.1 mm thick. Sample rods were grown under the conditions of Example 2 just after the short ingot was grown with one sample rod being center cut and the other sample rod being processed to form a center slab about 1.1 mm thick. To prepare the center cut sample rods, after the thermal donor kill anneal and a four hour wait time, the sample rod top and tail were removed and the rods were cut axially down the center line to make two half pieces. To prepare the center slabs, the sample rod top and tail were removed and the rods were cropped to form the center slab. After a mixed-acid etch (MAE), the center slab was subjected to a thermal donor kill anneal. Resistivity was measured after a four hour wait time. The resistivity of the center cut sample rods were measured with a two-point probe and the resistivity of the center slabs were measured with a four-point probe. A product ingot was also grown and the seed-end resistivity was measured. The resistivity measurements are shown in FIG. 9.

As shown in FIG. 9, axial variation is observed in the center cut sample rods. The center slab measurements included some random variation in axial measurements but with the average resistivity being relatively close to the short body (˜6200 ohm-cm). Resultant dopant addition would be similar if center slab resistivity was used to determine dopant addition (e.g., very small addition of phosphorous).

### Example 6: Comparison of Resistivity of Sequential Flat Grinds of a Sample Rod Verse Center Slab

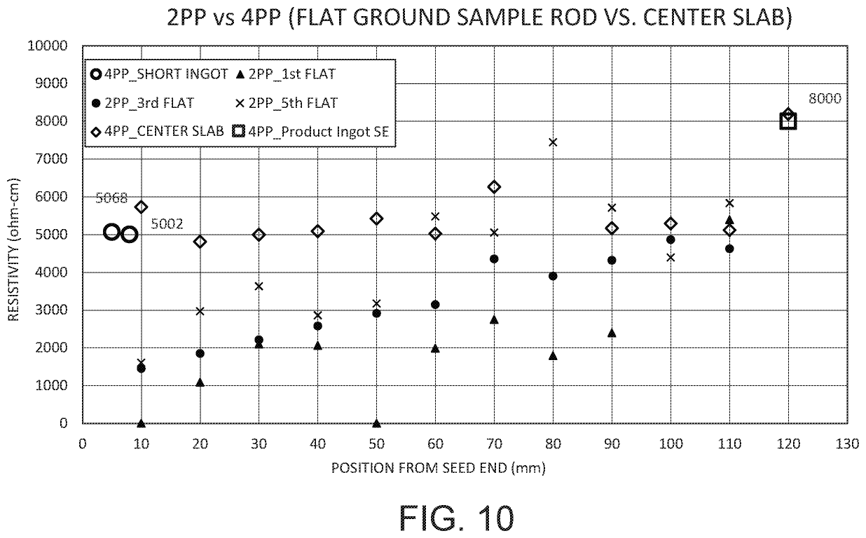

A sample rod was grown according to Example 2. The sample rod was sequentially ground with resistivity being measured with a two-point probe after each grind as in Example 4. A sample rod was also grown and processed to form a center slab about 1.1 mm thick. The resistivity of the center slab was measured by a four-point probe. A short ingot and product ingot were also grown after the sample rods were formed with the seed-end resistivity being measured from slugs. The resistivities are shown in FIG. 10.

As shown in FIG. 10, each flat measurement (1^{st}, 3^{rd}, and 5^{th} grinds being shown) included an axial trend from seed end to the opposite end with the overall average resistivity being below that of the short ingot. The center slab measurement shows a flatter axial trend with the overall average being very similar to the short body resistivity, resulting in a similar dopant addition.

### Example 7: Accuracy of the Resistivity Prediction

Table 1 shows the resistivity of a short ingot compared to the resistivity of a center slab cropped from a sample rod as measured by a four-point probe (“4PP”) and the resistivity of a sample rod with a planar segment ground into the sample rod as measured by a two-point probe (“2PP”). The short ingot was grown before the sample rods. The short ingot resistivity was measured at the opposite end of the short ingot (˜250 mm). The sample rod data points are the average of the axial resistivity from the seed end to the opposite end taken every 10 mm. A product ingot was grown with the resistivity at the seed end (˜150 mm body position) being shown in Table 1. The sample rods, short ingots and product ingots were grown in eight runs in accordance with the conditions of Example 2.

TABLE 1
Sample Rod, Short Ingot, and Product Ingot Resistivity Measurements

| | Sample | Sample | | | | |
|---|---|---|---|---|---|---|
| | Rod + 2PP | Rod Center | | | | |
| | Avg. | Slab + 4PP | | Rank | | |
| Short | Excluding | Exclude >+/− | Product | | Sample | Center |
| Ingot | Min & Max | 30% | Ingot | Ingot | Rod + 2PP | Slab + 4PP |
| 5002 | 3513 | 5290 | 8000 | 1 | 0 | 1 |
| 5306 | 2573 | 5932 | 8525 | 1 | 0 | 1 |
| 5350 | 5890 | 5411 | 8525 | 1 | 0.5 | 1 |
| 6302 | 6673 | 7737 | 9440 | 1 | 0.5 | 1 |
| 13320 | — | 7833 | 6531 | 0 | — | 1 |
| 8884 | 12262 | 9470 | 11000 | 1 | 0 | 1 |
| 9514 | 5047 | 7572 | 8160 | 1 | 0 | 1 |
| 9514 | 15180 | 8444 | 8160 | 1 | 0 | 1 |

As shown in Table 1, the short ingot resistivity and the sample rod center slab (4PP) resistivity are relatively similar and dopant addition by either result would have been directionally similar. The sample rod with the planar segment (2PP) included several results that are directionally opposite to the short body which would have caused a wrong dopant (i.e., P-type vs. N-type) to be added. This indicates that the sample rod center slab with four-point probe resistivity measurement predicts the resistivity of the product ingot with better accuracy.

### Example 8: Comparison of Two-point Probe Resistivity Measurement and Four-Point Probe Resistivity Measurement on Center Slab

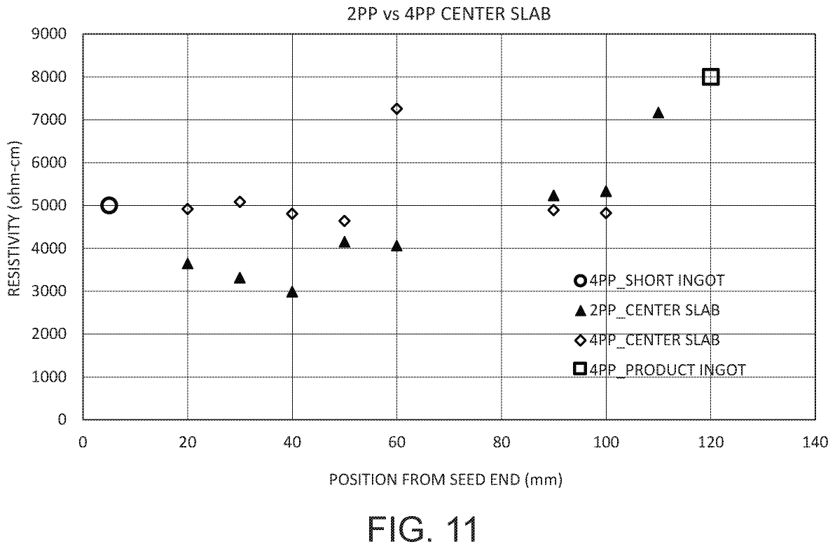

The resistivity of several center slabs cut from sample rods were measured with a two-point probe and were measured with a four-point probe. The short ingot resistivity (4PP) was also measured. As shown in FIG. 11, the two-point measurement and four-point measurement track relatively closely with the average axial resistivity being similar to the short ingot. This indicates that the axial variation in measurement between short sample rods with a planar segment and center slabs is caused by the physical volume of the sample and the amount of thickness variation compensation that is used.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

1. A method for producing a single crystal silicon ingot from a silicon melt held within a crucible comprising:
adding polycrystalline silicon to the crucible;
heating the polycrystalline silicon to cause a silicon melt to form in the crucible;
pulling a sample rod from the melt;
forming a slab from the sample rod;
measuring a resistivity of the slab by contacting the slab with a four-point probe; and
pulling a product ingot from the melt.

2. The method as set forth in claim 1 wherein the resistivity is measured by generating a current in the slab and measuring the voltage.

3. The method as set forth in claim 2 wherein the voltage is measured at two or more points along the length of the slab.

4. The method as set forth in claim 3 wherein the resistivity is calculated, at least in part, by factoring the sample length and average thickness of the slab.

5. The method as set forth in claim 1 wherein sample rod has a central axis, the slab being formed by:
cropping the sample rod along a first crop plane, the first crop plane being parallel to the central axis; and
cropping the sample rod along a second crop plane, the second crop plane being parallel to the central axis, wherein the slab comprises at least a portion of a central axis of the sample rod.

6. The method as set forth in claim 1 wherein the sample rod has a first end, a second end, and a central axis extending from the first end to the second end, the slab comprising at least about 50% of the central axis of the sample rod.

7. The method as set forth in claim 1 wherein the sample rod has a first end, a second end, and a central axis extending from the first end to the second end, the central axis of the sample rod extending through the length of the slab.

8. The method as set forth in claim 1 wherein the slab has a thickness of between about 3 mm and about 0.5 mm.

9. The method as set forth in claim 1 wherein the sample rod and the product ingot each have a diameter, the diameter of the sample rod being less than the diameter of the product ingot.

10. The method as set forth in claim 9 wherein the diameter of the sample rod is less than 0.25 times the diameter of the product ingot.

11. The method as set forth in claim 1 wherein the sample rod has a length of less than about 100 mm.

12. The method as set forth in claim 1 wherein the product ingot has a resistivity of at least about 6,000 Ω-cm.

13. The method as set forth in claim 1 wherein the sample rod has a resistivity of at least about 10,000 Ω-cm.

14. The method as set forth in claim 1 wherein one or more growth conditions of the product ingot is adjusted based on the measured resistivity of the slab.

15. A method for producing a single crystal silicon ingot from a silicon melt held within a crucible comprising:
adding polycrystalline silicon to the crucible;
heating the polycrystalline silicon to cause a silicon melt to form in the crucible;
pulling a sample rod from the melt;
cropping a slab from the sample rod;
annealing the slab to annihilate thermal donors;
lapping the annealed slab to form a lapped surface;
measuring a resistivity of the slab by contacting the lapped surface with a four-point probe; and
adjusting an amount of dopant added to the melt based at least in part on the measured resistivity of the slab to achieve a target resistivity in a product ingot; and
pulling the product ingot from the melt.

16. The method as set forth in claim 15 wherein the sample rod and the product ingot each have a diameter, the diameter of the sample rod being less than the diameter of the product ingot.

17. The method as set forth in claim 15 wherein sample rod has a central axis, the slab being formed by:
cropping the sample rod along a first crop plane, the first crop plane being parallel to the central axis; and
cropping the sample rod along a second crop plane, the second crop plane being parallel to the central axis, wherein the slab comprises at least a portion of a central axis of the sample rod.

18. The method as set forth in claim 15 wherein the product ingot has a resistivity of at least about 6,000 Ω-cm.

19. The method as set forth in claim 15 wherein the slab has a thickness of between about 5 mm and about 0.1 mm.

20. The method as set forth in claim 15 wherein the sample rod has a length of less than about 200 mm.
